(19) United States
(12) Patent Application Publication
(10) Pub. No.: US 2017/0186644 A1
(43) Pub. Date: Jun. 29, 2017

(54) METHOD FOR MAKING AN INTEGRATED CIRCUIT (IC) PACKAGE WITH AN ELECTRICALLY CONDUCTIVE SHIELD LAYER

(71) Applicant: STMICROELECTRONICS PTE LTD, Singapore (SG)

(72) Inventors: Laurent HERARD, Singapore (SG); David GANI, Choa Chu kang (SG)

(21) Appl. No.: 14/982,103

(22) Filed: Dec. 29, 2015

(51) Int. Cl. H01L 21/78; H01L 21/48; H01L 21/56

(52) U.S. Cl. CPC H01L 21/78; H01L 21/565; H01L 21/4871; H01L 21/4853

(57) ABSTRACT

A method for making at least one integrated circuit (IC) package includes positioning an electrically conductive shield layer adjacent an interior of a mold, and coupling the mold onto a substrate carrying at least one IC thereon. A molding material is supplied into the interior of the mold to form an encapsulated body over the at least one IC and substrate with the electrically conductive shield layer at an outer surface of the encapsulated body.

### FIELD OF THE INVENTION

The present invention refers to the field of integrated circuit (IC) packages, and more particularly, to electrically shielding an IC package.

### BACKGROUND OF THE INVENTION

There exists a general need in wireless communications devices for certain integrated circuit (IC) packages to be isolated from electromagnetic interference (EMI) in order to maintain proper device performance. The electromagnetic interference may be received from, or transmitted to, the environment.

One approach for shielding an IC package from electromagnetic interference is to cover the IC package with a grounded metal enclosure typically called a can. However, this approach may be costly and lacks design flexibility. In addition, the metal can adds weight and adds significant size to the IC package footprint.

Another approach is to use a physical vapor deposition (PVD) process that deposits in a vacuum chamber a conductive layer on an upper surface of the IC package. Sputtering is a type of PVD that involves ejecting material from a target that is a source onto a substrate (such as an IC package) in a vacuum chamber. However, this approach is expensive and is a separate stand alone process which extends the process flow for making the IC package. Consequently, there is a need for electrically shielding an IC package in a relatively straightforward manner.

### SUMMARY OF THE INVENTION

One aspect is directed to a method for making a plurality of integrated circuit (IC) packages. The method may include positioning an electrically conductive shield layer adjacent an interior of a mold, with the electrically conductive shield layer being carried by a film, coupling the mold onto a substrate carrying a plurality of ICs thereon, and supplying a molding material into the interior of the mold to form an encapsulated body over the plurality of ICs and substrate with the electrically conductive shield layer at an outer surface of the encapsulated body. The mold from the encapsulated body may be separated so that the film is separated from the electrically conductive shield layer.

The method may further comprise dividing the substrate to provide the plurality of IC packages. Each IC package may have the electrically conductive shield layer only on an upper surface of the encapsulated body.

Using the electrically conductive shield layer advantageously eliminates having to perform extra processing steps for shielding the ICs. Use of the electrically conductive shield layer also provides a uniform shielding layer thickness as well as reducing processing costs.

Another aspect is directed to method for making a single IC package. The method may comprise positioning an electrically conductive shield layer adjacent an interior of a mold, with the electrically conductive shield layer being carried by a film. A molding material may be supplied into the interior of the mold. The substrate carrying the IC thereon may be coupled to the mold to form an encapsulated body over the IC and substrate with the electrically conductive shield layer at an outer surface of the encapsulated body. The encapsulated body may be separated from the mold so that the film is separated from the electrically conductive shield layer.

The electrically conductive shield layer may remain on sidewalls of the encapsulated body. The substrate may carry at least one electrical conductor thereon. To better protect the IC package from electromagnetic interference, the electrically conductive shield layer may be coupled to the at least one electrical conductor.

### BRIEF DESCRIPTION OF THE DRAWINGS

FIG. 1 is flowchart for making a plurality of integrated circuit (IC) packages each including an electrically conductive shield layer in accordance with the present invention.

FIGS. 2-5 are cross-sectional views of the plurality of IC packages at different manufacturing steps based on the flowchart in FIG. 1.

FIG. 6 is a cross-sectional view of the plurality of IC packages made based on the flowchart in FIG. 1.

FIG. 7 is flowchart for making a single IC package including an electrically conductive shield layer in accordance with the present invention.

FIGS. 8-11 are cross-sectional views of the single IC package at different manufacturing steps based on the flowchart in FIG. 1.

FIG. 12 is a cross-sectional view of the single IC package made based on the flowchart in FIG. 7.

### DETAILED DESCRIPTION OF THE PREFERRED EMBODIMENTS

The present invention will now be described more fully hereinafter with reference to the accompanying drawings, in which preferred embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. Like numbers refer to like elements throughout.

A method for making at least one integrated circuit (IC) package with an electrically conductive shield layer will be discussed in detail below. In general, the method includes positioning an electrically conductive shield layer adjacent an interior of a mold, and coupling the mold onto a substrate carrying at least one IC thereon. A molding material is supplied into the interior of the mold to form an encapsulated body over the at least one IC and substrate with the electrically conductive shield layer at an outer surface of the encapsulated body. Alternatively, the molding material may be supplied into the interior of the mold before coupling the mold onto the substrate carrying at least one IC thereon.

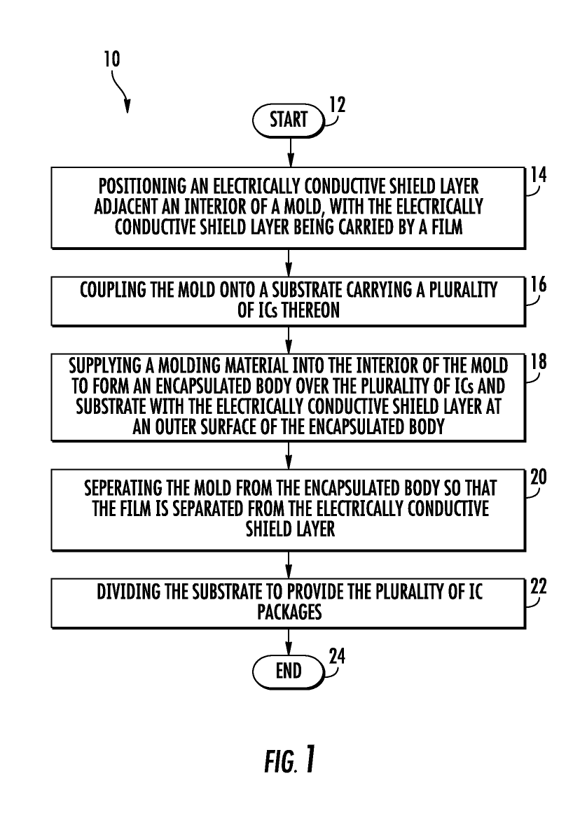

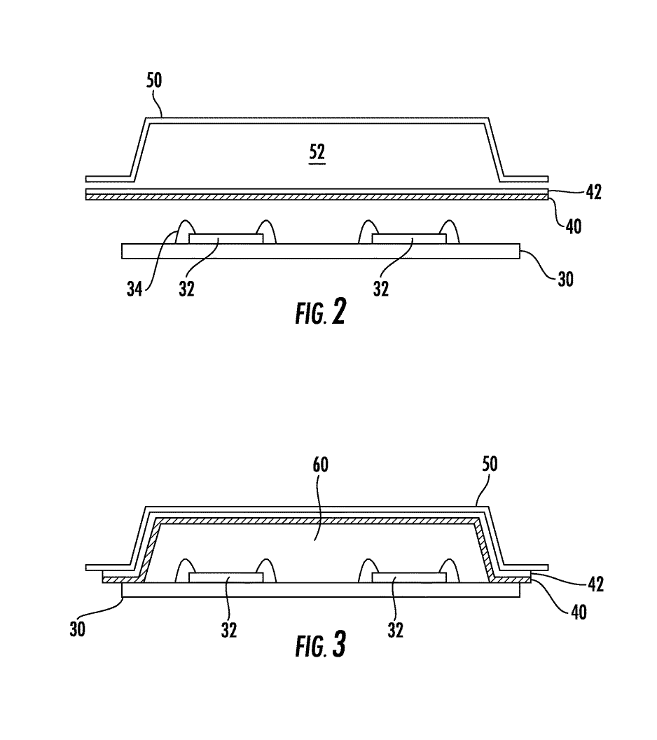

Referring now to the flowchart 10 illustrated in FIG. 1 and to the cross-sectional views in FIGS. 2-6, a method for making a plurality of IC packages 70 will be discussed, with each IC package including an electrically conductive shield layer 40.

In the illustrated embodiment, a substrate 30 is carrying a plurality of ICs 32, as illustrated in FIG. 2. Contacts on the each IC 32 are wire bonded 34 to bumps on the substrate 30. From the start (Block 12), the method comprises positioning at Block 14 the electrically conductive shield layer 40 adjacent an interior 52 of a mold 50. The electrically conductive shield layer 40 is carried by a film 42.

As readily understood by those skilled in the art, the film 42 is used in film-assisted molding. The film 42 may be a tape, for example. In film-assisted molding, a vacuum is used to suck the film 42 along with the electrically conductive shield layer 40 into the interior 52 of the mold 50 before molding material is supplied into the interior.

The mold 50 is coupled at Block 16 onto the substrate 30 carrying the plurality of ICs 32 thereon. A molding material is supplied at Block 18 into the interior 52 of the mold 50 to form an encapsulated body 60 over the plurality of ICs 32 and the substrate 30 with the electrically conductive shield layer 40 at an outer surface of the encapsulated body, as illustrated in FIG. 3. The illustrated molding process is referred to as transfer molding.

Transfer molding equipment for electronic components typically includes a press equipped with platens, one of which contains a chamber known as a pot, in which the molding material is placed and liquified by a combination of heat and pressure. A piston or plunger transfers the melt material into cavities of the mold 50 via a series of channels known as runners. The typical temperature of the molding process is within a range of 150-200° C. and the pressure ranges from 3 to 100 bar.

The heat from the molding process helps to cure the electrically conductive shield layer 40 to the encapsulated body 60. The film has a thickness within a range of 70-100 microns, and the electrically conductive shield layer 40 has a thickness within a range of 20-30 microns.

After the encapsulation, the mold 50 is separated from the encapsulated body 60 at Block 20 so that the film 42 is separated from the electrically conductive shield layer 40, as illustrated in FIG. 4. When the mold 50 is removed, the electrically conductive shield layer 40 is on an upper surface and sidewalls of the encapsulated body 60. Outer portions 41 of the electrically conductive shield layer 40 that extend past the encapsulated body 60 may remain with the film 40, as also illustrated in FIG. 4.

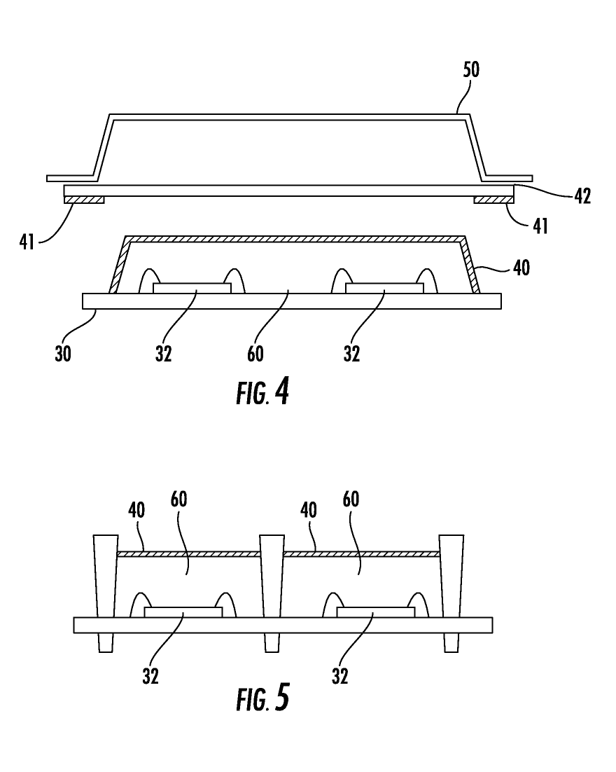

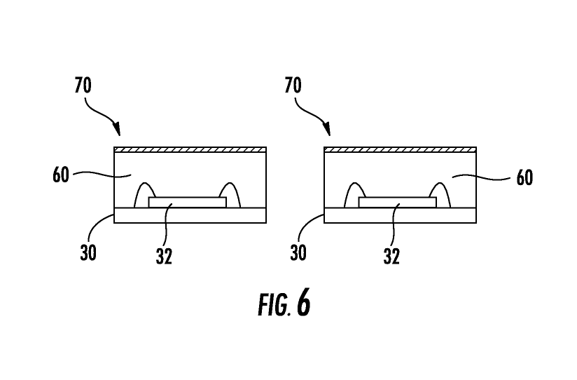

The substrate 30 is divided at Block 22 to provide the plurality of IC packages 70, as illustrated in FIGS. 5 and 6. The electrically conductive shield layer 40 is now only on the upper surface of the encapsulated body 60.

Using the electrically conductive shield layer 40 during the film-assisted molding advantageously eliminates having to perform extra steps for shielding the ICs 32. Use of the electrically conductive shield layer 40 also provides a uniform shielding layer thickness as well as reducing processing costs. The method ends at Block 24.

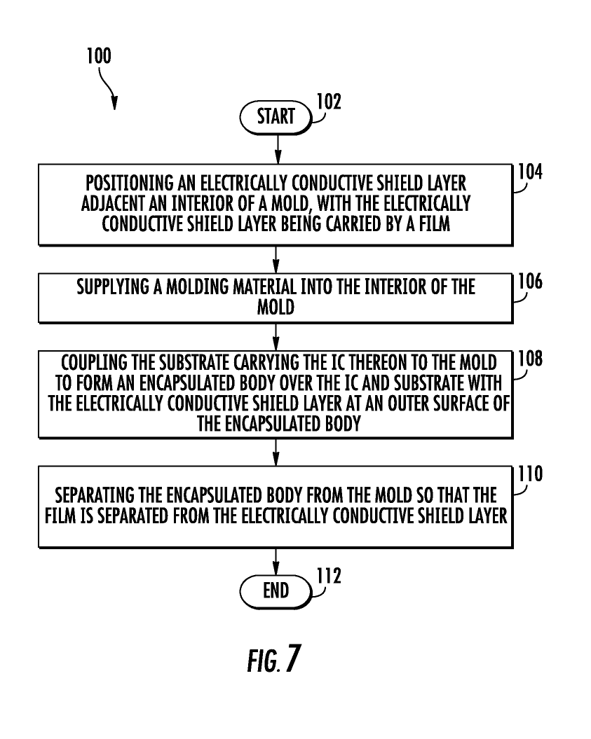

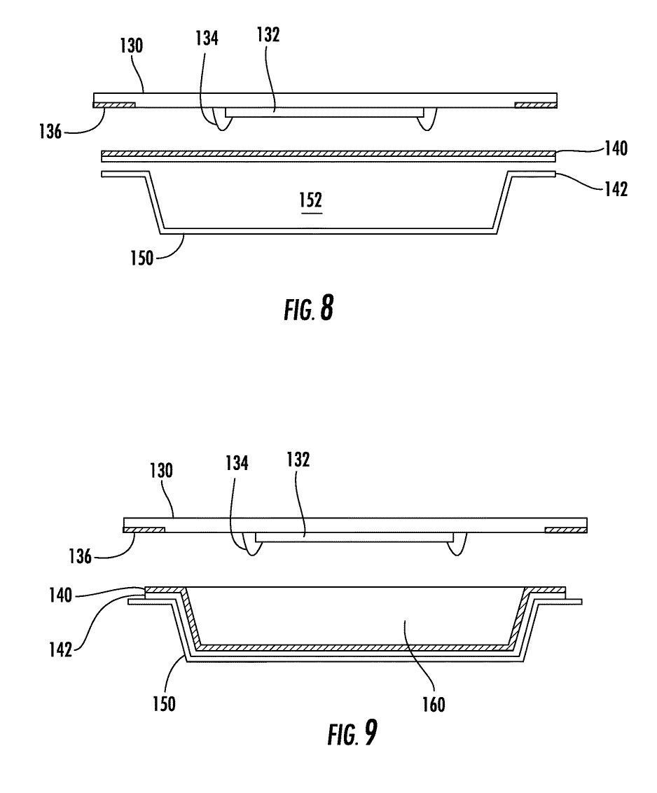

Referring now to the flowchart 100 illustrated in FIG. 7 and to the cross-sectional views in FIGS. 8-12, a method for making a single IC package 170 will be discussed, with the IC package including an electrically conductive shield layer 140. An advantage of making the single IC package 170 is that the electrically conductive shield layer 140 may further remain on sidewalls of the encapsulated body 160. Alternatively, the method may be used to make a plurality of IC packages.

In the illustrated embodiment, a substrate 130 is carrying a single IC 132, as illustrated in FIG. 8. Contacts on the IC 132 are wire bonded 134 to the substrate 130. The substrate 130 may also carry exposed electrical conductors 136. The electrical conductors 136 are grounded, for example.

From the start (Block 102), the method comprises positioning at Block 104 the electrically conductive shield layer 140 adjacent an interior 152 of a mold 150. The electrically conductive shield layer 140 is carried by a film 142.

The illustrated molding process in this embodiment is compression molding. Orientation of the substrate 130 and the mold 150 is reversed as compared to the above illustrated transfer molding. In compression molding, a molding material is supplied at Block 106 into the interior 152 of the mold 150, as illustrated in FIG. 9. The molding material is generally preheated.

As discussed above, the film 132 may be a tape, for example. In film-assisted molding, a vacuum is used to suck the film 132 along with the electrically conductive shield layer 140 into the interior 152 of the mold 150 before molding material is supplied into the interior.

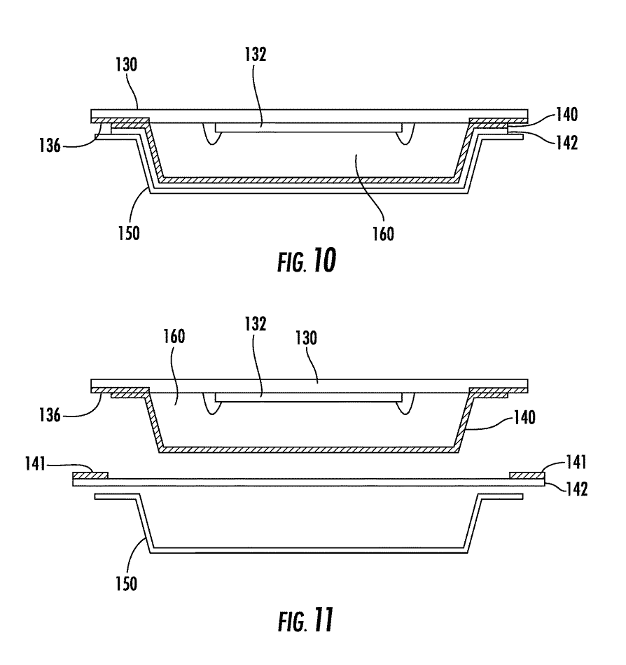

The substrate 130 carrying the IC 132 thereon is coupled to the mold 150 at Block 108 to form an encapsulated body 160 over the IC 132 and the substrate 130 with the electrically conductive shield layer 140 at an outer surface of the encapsulated body, as illustrated in FIG. 10.

The heat from the molding process helps to cure the electrically conductive shield layer 140 to the encapsulated body 160. The film has a thickness within a range of 70-100 microns, and the electrically conductive shield layer 140 has a thickness within a range of 20-30 microns.

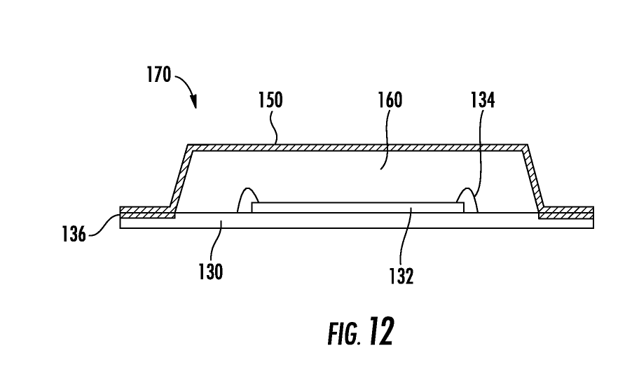

After the encapsulation, the encapsulated body 160 is separated from the mold 150 at Block 110 so that the film 142 is separated from the electrically conductive shield layer 140, as illustrated in FIG. 11. When the mold 50 is removed, the electrically conductive shield layer 140 is on an upper surface and sidewalls of the encapsulated body 160, as illustrated in FIG. 12. Outer portions 141 of the electrically conductive shield layer 140 that extend past the encapsulated body 160 may remain with the film 140, as also illustrated in FIG. 11.

To better protect the IC package 170 from electromagnetic interference, the electrically conductive shield layer 140 is coupled to the at least one electrical conductor 136. Using the electrically conductive shield layer 140 during the film-assisted molding advantageously eliminates having to perform extra steps for shielding the IC 132. Use of the electrically conductive shield layer 140 also provides a uniform shielding layer thickness as well as reducing processing costs. The method ends at Block 112.

Many modifications and other embodiments of the invention will come to the mind of one skilled in the art having the benefit of the teachings presented in the foregoing descriptions and the associated drawings. Therefore, it is understood that the invention is not to be limited to the specific embodiments disclosed, and that modifications and embodiments are intended to be included within the scope of the appended claims.

1. A method for making at least one integrated circuit (IC) package comprising:
positioning an electrically conductive shield layer adjacent an interior of a mold;
coupling the mold onto a substrate carrying at least one IC thereon; and
supplying a molding material into the interior of the mold to form an encapsulated body over the at least one IC and substrate with the electrically conductive shield layer at an outer surface of the encapsulated body; and
separating the mold from the encapsulated body so that outer portions of the electrically conductive shield layer extending past the encapsulated body remaining with the mold.

2. The method according to claim 1 wherein the electrically conductive shield layer is carried by a film.

3. The method according to claim 2 wherein the outer portions of the electrically conductive shield layer are carried by the film after the separating.

4. The method according to claim 2 wherein the film has a thickness within a range of 70-100 microns.

5. The method according to claim 2 wherein the electrically conductive shield layer has a thickness within a range of 20-30 microns.

6. The method according to claim 1 wherein the at least one IC comprises a plurality of ICs; and further comprising dividing the substrate to provide a plurality of IC packages.

7. The method according to claim 6 wherein each IC package has the electrically conductive shield layer only on an upper surface of the encapsulated body.

8. (canceled)

9. (canceled)

10. (canceled)

11. A method for making a plurality of integrated circuit (IC) packages comprising:
positioning an electrically conductive shield layer adjacent an interior of a mold, with the electrically conductive shield layer being carried by a film;
coupling the mold onto a substrate carrying a plurality of ICs thereon;
supplying a molding material into the interior of the mold to form an encapsulated body over the plurality of ICs and substrate with the electrically conductive shield layer at an outer surface of the encapsulated body;
separating the mold from the encapsulated body so that the film is separated from the electrically conductive shield layer, with outer portions of the electrically conductive shield layer extending past the encapsulated body remaining with the film and the mold; and
dividing the substrate to provide the plurality of IC packages.

12. The method according to claim 11 wherein the film has a thickness within a range of 70-100 microns.

13. The method according to claim 11 wherein the electrically conductive shield layer has a thickness within a range of 20-30 microns.

14. The method according to claim 11 wherein each IC package has the electrically conductive shield layer only on an upper surface of the encapsulated body.

15. A method for making an integrated circuit (IC) package comprising:
positioning an electrically conductive shield layer adjacent an interior of a mold, with the electrically conductive shield layer being carried by a film;
supplying a molding material into the interior of the mold;
coupling the substrate carrying the IC thereon to the mold to form an encapsulated body over the IC and substrate with the electrically conductive shield layer at an outer surface of the encapsulated body; and
separating the encapsulated body from the mold so that the film is separated from the electrically conductive shield layer, with outer portions of the electrically conductive shield layer extending past the encapsulated body remaining with the film and the mold.

16. The method according to claim 15 wherein the film has a thickness within a range of 70-100 microns.

17. The method according to claim 15 wherein the electrically conductive shield layer has a thickness within a range of 20-30 microns.

18. (canceled)

19. (canceled)
